(19) United States
(12) Patent Application Publication
(10) Pub. No.: US 2015/0285888 A1
(43) Pub. Date: Oct. 8, 2015

(54) METHOD FOR MAGNETIC RESONANCE IMAGING BY OPERATION OF A MAGNETIC RESONANCE APPARATUS

(71) Applicant: Siemens Aktiengesellschaft, Muenchen (DE)

(72) Inventor: David Grodzki, Erlangen (DE)

(73) Assignee: Siemens Aktiengesellschaft, Muenchen (DE)

(21) Appl. No.: 14/676,989

(22) Filed: Apr. 2, 2015

(30) Foreign Application Priority Data
Apr. 2, 2014 (DE) 102014206253.5

(51) Int. Cl. G01R 33/56; G01R 33/54

(52) U.S. Cl. CPC G01R 33/56; G01R 33/543

(57) ABSTRACT

In a method and apparatus for magnetic resonance (MR) with oversampling, a first 2D or 3D data acquisition range is selected and a second 2D or 3D data acquisition range is automatically determined such that the second range includes the first range and a 2D or 3 D MR signal-generating range. MR image data are acquired from the entire second range. An image is reconstructed from the MR image data, the image corresponding to the first range.

### BACKGROUND OF THE INVENTION

1. Field of the Invention

The invention relates to a method for magnetic resonance imaging by operation of a magnetic resonance apparatus, and to a magnetic resonance apparatus.

2. Description of the Prior Art

In a magnetic resonance apparatus, also called a magnetic resonance tomography system, the body to be examined of an examination person, in particular a patient, is conventionally exposed to a relatively high basic magnetic field, for example of 1.5 or 3 or 7 tesla, with the use of a basic field magnet. In addition, gradient fields are produced with the use of a gradient coil system. Radio-frequency pulses, in particular excitation pulses, are then emitted by a radio-frequency antenna unit by suitable antenna devices, and this causes the nuclear spins of specific atoms resonantly excited by these radio-frequency pulses to be tilted by a defined flip angle with respect to the magnetic field lines of the basic magnetic field. When the nuclear spins relax, radio-frequency signals, known as magnetic resonance signals, are emitted that are received by suitable radio-frequency antennas, and then processed further. The desired image data can be reconstructed from the raw data acquired in this way.

For a specific measurement, a specific magnetic resonance sequence, also called a pulse sequence, is to be emitted, which is composed of a sequence of radio-frequency pulses, in particular excitation pulses and refocusing pulses, and compatible therewith, gradient fields to be emitted coordinated therewith in different gradient axes in different spatial directions. Readout windows are set coordinated therewith in terms of time, and these specify the time frames in which the induced magnetic resonance signals are detected.

Signal folding can occur during magnetic resonance imaging. This may be avoided by means of oversampling of the magnetic resonance signals.

### SUMMARY OF THE INVENTION

An object of the invention is to provide an improved method of oversampling in magnetic resonance imaging.

This object is achieved in accordance with the invention by a method for magnetic resonance imaging by operation of a magnetic resonance apparatus, the method including selecting a first recording range, automatically determining a second recording range such that the second recording range includes the first recording range and a magnetic resonance signal-generating range, acquiring magnetic resonance image data from the entire second recording range, and emitting an image range of the magnetic resonance image data as an output, wherein the image range corresponds to the first recording range.

Magnetic resonance image data of an examination object are recorded (acquired) by the magnetic resonance apparatus. The examination object may be a patient, a training person or a phantom.

The recording range is also called an examination volume or field of view, and thus a spatial data acquisition range. The recording range can be two-dimensional or three-dimensional.

The first recording range describes a section of the examination object which is of interest for magnetic resonance imaging. The first recording range is manually selected by a user, via an interface of a control computer of the image data acquisition scanner. The first recording range can be selected, for example, based on a previously recorded overview image. The user can manually set the limits of the first recording range via the input interface. The user can also set, for example, a number of slices to be recorded and/or a resolution for the first recording range.

The second recording range is determined automatically by the control computer such that the first recording range is at least a section of the second recording range. The second recording range can completely include the first recording range for this purpose. In addition to the first recording range, the second recording range can include a further recording range which, when combined with the first recording range, is called the magnetic resonance signal-generating range. The range from which magnetic resonance signals, which are greater than a noise value, are recorded is regarded as the magnetic resonance signal-generating range. The magnetic resonance signal-generating range can therefore also depend on a configuration of activated coil elements of a receiving coil for receiving the magnetic resonance signals. For example, the configuration of the activated coil elements can be selected in such a way that the activated coil elements are designed for detecting magnetic resonance signals from a greater range than from the first recording range. The second recording range is therefore usually bigger than the first recording range. This is the case if the user has selected the first recording range in such a way that some of the magnetic resonance signal-generating range is located outside of the first recording range.

The second recording range is selected such a way that an entire signal-generating volume is covered during acquisition of the magnetic resonance image data. The second recording range is therefore automatically determined in such a way that folding of magnetic resonance signals from outside of the first recording range is avoided in the first recording range. This undesirable folding of the magnetic resonance signals, also called wrap-around artifact, occurs in particular if, during acquisition of magnetic resonance image data, the magnetic resonance signal-generating range is located partially outside of the recording range.

According to the proposed approach, the magnetic resonance image data are acquired from the second recording range. Since the second recording range was automatically selected in such a way that it includes the magnetic resonance signal-generating range, folding of magnetic resonance signals can be avoided. The acquisition of magnetic resonance image data from the second recording range includes acquisition of raw data from the second recording range and a reconstruction of the magnetic resonance image data using the acquired raw data. This approach has the advantage that when selecting the first recording range, the user does not have to ensure that the first recording range includes the complete magnetic resonance signal-generating range. The user therefore does not have to worry about potential folding of magnetic resonance signals during acquisition of the magnetic resonance image data when selecting the first recording range. Furthermore, artifacts on magnetic resonance image data can also be avoided in this way. An image quality of the magnetic resonance image data can therefore be ensured or increased. Inexperienced users, for example, can also record artefact-free magnetic resonance image data. The user can also select any small first recording range without artifacts occurring in the magnetic resonance image data, because the second recording range has the size necessary for avoiding artifacts.

Furthermore, according to the proposed approach, only the image range of the magnetic resonance image data which corresponds to the first recording range is output to the user. The image range is therefore in particular a section of the magnetic resonance image data. The image range corresponds in particular to the first recording range, by way of example according to its spatial dimensions and/or spatial position and/or spatial boundaries. The image range is output to the user in particular on a display unit, by way of example a monitor. Accordingly, during image reconstruction, firstly magnetic resonance image data is reconstructed from the entire second recording range, with only the portion of the magnetic resonance image data of interest to the user being output thereafter. This approach has the advantage that the user, by way of example a radiologist, is only provided with the image range of the magnetic resonance image data which is of interest to the user. The section of the magnetic resonance image data, which is not part of the first recording range, is accordingly advantageously cut before output. This section of the magnetic resonance image data is therefore preferably not output for the user. The magnetic resonance image data is acquired and the image range cut automatically in the background. The user therefore advantageously does not know that magnetic resonance image data is acquired from a larger second recording range. The user can therefore concentrate on the image range of the magnetic resonance image data of interest, which he has indeed manually determined.

In an embodiment, automatically determining the second recording range includes automatically determining at least one oversampling factor for the first recording range. The oversampling factor for a spatial direction indicates in particular by which factor the spatial extent of the first recording range must be elongated in this spatial direction for the spatial extent of the second recording range to result in this spatial direction. In other words, the oversampling factor for a spatial direction indicates in particular by which factor the spatial extent of the second recording range is increased in this spatial direction compared to the spatial extent of the first recording range. The oversampling factor is therefore in particular greater than one. The oversampling factor can be determined separately for each spatial direction of the first recording range. It may also be the same for all spatial directions of the first recording range. This is in particular the case if, as described in one of the following paragraphs, the magnetic resonance image data is non-selectively acquired. The oversampling factor is automatically determined in such a way that the second recording range includes the first recording range and the magnetic resonance signal-generating range. The oversampling factor is therefore determined in such a way that artifacts due to folding of magnetic resonance signals are avoided during acquisition of the magnetic resonance image data.

In an embodiment, preliminary magnetic resonance image data are acquired, with the second recording range being determined using the preliminary magnetic resonance image data. The preliminary magnetic resonance image data are acquired before the automatic determination of the second recording range. The acquisition and reconstruction of the preliminary magnetic resonance image data is already concluded with the determination of the second recording range. The preliminary magnetic resonance image data can therefore be acquired in a pre-measurement. The same coil elements of the receiving coil which are also activated when acquiring the magnetic resonance image data from the entire second recording range are activated when acquiring the preliminary magnetic resonance image data. The preliminary magnetic resonance image data can be dedicatedly acquired for the determination of the second recording range. Alternatively or additionally, medical preliminary magnetic resonance image data provided for consideration by the user may also be acquired. Alternatively or additionally, the image data that are acquired during a prescan-normalize measurement or a coil sensitivity measurement may be used as the preliminary magnetic resonance image data. The preliminary magnetic resonance image data are recorded from a preliminary recording range that is larger than the first recording range. The preliminary recording range is also advantageously selected in such a way that it is at all events larger than the second recording range. The preliminary recording range is selected in such a way that it includes all ranges of the examination object that potentially form part of the magnetic resonance signal-generating range. The preliminary magnetic resonance image data can therefore be used to determine the magnetic resonance signal-generating range. Using the preliminary magnetic resonance image data it may therefore be determined from which ranges of the examination object magnetic resonance signals are being received by means of the activated coil elements. The acquired preliminary magnetic resonance image data therefore provide a particularly advantageous starting point for determination of the second recording range.

One embodiment provides that the second recording range is determined using the preliminary magnetic resonance image data in such a way that the second recording range includes all signal ranges of the preliminary magnetic resonance image data having a signal value which is greater than a signal threshold value. The second recording range is therefore determined as a section of the preliminary recording range of the preliminary magnetic resonance image data. The second recording range is therefore smaller than the preliminary recording range of the preliminary magnetic resonance image data. The signal ranges of the preliminary magnetic resonance image data having the signal value which is greater than the signal threshold value then set the magnetic resonance signal-generating range. The second recording range can of course also include signal ranges of the preliminary magnetic resonance image data having a signal value which is smaller than the signal threshold value. This may be necessary if the second recording range must be selected so as to be rectangular or cuboidal. The signal threshold value can be automatically and/or manually set. The signal threshold value is selected in such a way that signals, which are smaller than the signal threshold value, do not interfere with the magnetic resonance image data in the case of potential folding in the magnetic resonance image data. The second recording range can therefore be determined using the preliminary magnetic resonance image data.

In an embodiment, the signal threshold value is greater than a mean noise signal of the preliminary magnetic resonance image data. The signal threshold value can be selected, for example as a multiple of, such as double or treble, the mean noise signal. The mean noise signal of the preliminary magnetic resonance image data can be a variation in the signal strength of the preliminary image data. Methods for determining the mean noise signal are known to those skilled in the art. The mean noise signal is determined by way of example when determining a signal-to-noise ratio. The mean noise signal provides a particularly advantageous base for the determination of the signal threshold value since signals which are smaller than the mean noise signal are typically unproblematic in relation to folding in the magnetic resonance image data.

In an embodiment, the preliminary magnetic resonance image data has a lower resolution than the magnetic resonance image data. The preliminary magnetic resonance image data can therefore be acquired particularly quickly and in a time-saving manner. Since the preliminary magnetic resonance image data is in particular not made available to a user, and is instead used for the determination of the second recording range, a low resolution of the preliminary magnetic resonance image data is typically sufficient.

In another embodiment, the magnetic resonance image data is non-selectively acquired from the entire second recording range. In the case of non-selective acquisition of the magnetic resonance image data, there is typically an excitation of the nuclear spin over all slices of the magnetic resonance image data. In the case of a non-selective acquisition of the magnetic resonance image data there is therefore no slice-selective excitation of the nuclear spin. Non-selectively acquired magnetic resonance image data are therefore usually isotropic. In contrast thereto, there is typically a slice-selective excitation of the nuclear spins in the case of selective acquisition of magnetic resonance image data. In the case of non-selective acquisition of magnetic resonance image data, signals from all three spatial directions can be folded in the magnetic resonance image data. The proposed approach is therefore particularly advantageous in the case of non-selective acquisition of the magnetic resonance image data, since non-selectively acquired magnetic resonance image data has an increased risk of signal folding. In the case of non-selective acquisition of the magnetic resonance image data it is therefore expedient to carry out oversampling in all three spatial directions.

In another embodiment, the second recording range is determined in such that signal folding in the image range is avoided when acquiring the magnetic resonance image data. For this purpose the size of the second recording range is advantageously selected at least in such a way that signal folding is avoided. Artifact-free magnetic resonance image data can therefore be produced. The magnetic resonance image data therefore has a high image quality.

The invention also encompasses a magnetic resonance apparatus, having an input unit, a display unit, an image data acquisition unit (scanner) and an arithmetic unit that has a determination unit. The input unit is configured to select a first recording range. The determination unit is configured to automatically determine a second recording range such that the second recording range includes the first recording range and a magnetic resonance signal-generating range. The image data acquisition unit is configured to acquire magnetic resonance image data from the entire second recording range. The display unit is configured to emit an image range of the magnetic resonance image data, wherein the image range corresponds to the first recording range.

According to an embodiment of the magnetic resonance apparatus, the determination unit is configured so that the automatic determination of the second recording range includes automatic determination of at least one oversampling factor for the first recording range.

In another embodiment of the magnetic resonance apparatus, the determination unit and the image data acquisition unit are configured so that preliminary magnetic resonance image data re acquired, and the second recording range is determined using the preliminary magnetic resonance image data.

In another embodiment of the magnetic resonance apparatus, the determination unit is configured so that the second recording range is determined using the preliminary magnetic resonance image data in such a way that the second recording range includes all signal ranges of the preliminary magnetic resonance image data having a signal value which is greater than a signal threshold value.

In another embodiment of the magnetic resonance apparatus, the determination unit is configured such that the signal threshold value is greater than a mean noise signal of the preliminary magnetic resonance image data.

In another embodiment of the magnetic resonance apparatus, the image data acquisition unit is configured such that the preliminary magnetic resonance image data have a lower resolution than the magnetic resonance image data.

In another embodiment of the magnetic resonance apparatus, the image data acquisition unit is configured such that the magnetic resonance image data are non-selectively selective acquired from the entire second recording range.

In another embodiment of the magnetic resonance apparatus, the image data acquisition unit is configured such that the second recording range is determined so that signal folding in the image range is avoided when acquiring the magnetic resonance image data.

The advantages of the inventive magnetic resonance apparatus substantially correspond to the advantages of the inventive method, as described above. Features, advantages or alternative embodiments mentioned in this connection are applicable to the apparatus as well

### BRIEF DESCRIPTION OF THE DRAWINGS

FIG. 1 shows an inventive magnetic resonance device in a schematic illustration.

FIG. 2 is a flowchart of a first embodiment of an inventive method.

FIG. 3 is a flowchart of a second embodiment of an inventive method.

FIG. 4 is a schematic illustration for explaining the inventive approach.

### DESCRIPTION OF THE PREFERRED EMBODIMENTS

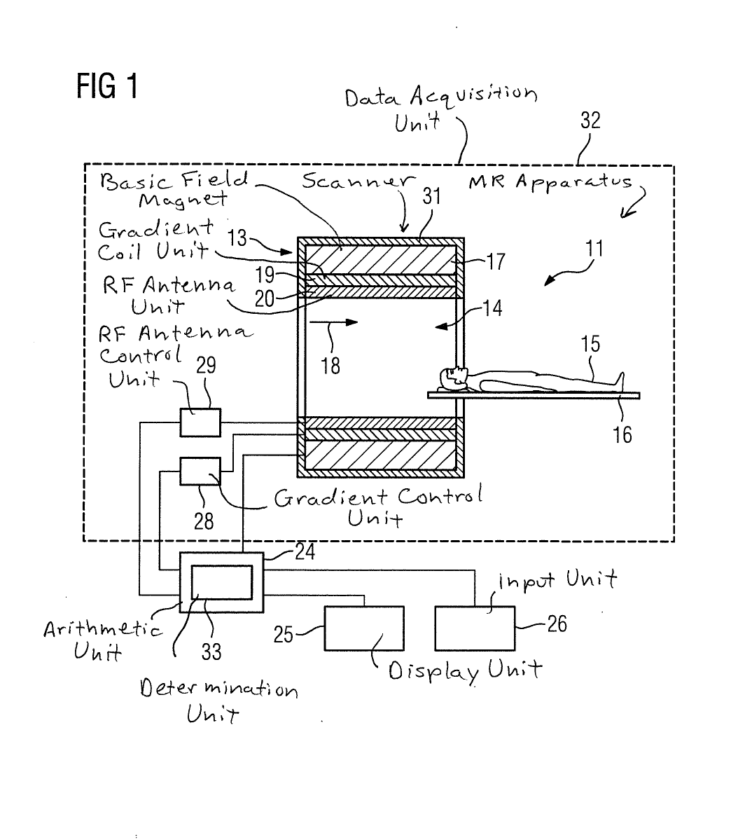

FIG. 1 schematically shows an inventive magnetic resonance (MR) apparatus 11. The magnetic resonance apparatus 11 has a scanner 13, having a basic field magnet 17 for generating a strong and, in particular, constant basic magnetic field 18. The scanner 13 has a cylindrical patient-receiving region 14 for receiving a patient 15, with the patient-receiving region 14 being cylindrically surrounded in a circumferential direction by the scanner 13. The patient 15 can be moved by patient-support device 16 of the scanner 13 into the patient-receiving region 14. The patient-support device 16 has for this purpose a bed that is movably arranged inside the scanner 13. The scanner 13 is shielded from the outside by a housing 31.

The scanner 13 also has a gradient coil unit 19 for generating magnetic field gradients which are used for spatial encoding during imaging. The gradient coil unit 19 is activated by means of a gradient control unit 28. The scanner 13 also has a radio-frequency (RF) antenna unit 20, which in the illustrated case is designed as a body coil permanently integrated in the scanner 13, and a radio-frequency antenna control unit 29 for excitation of nuclear spins in the patient 15 by producing a magnetization thereof relative to the basic magnetic field 18 generated by the basic field magnet 17. The radio-frequency antenna unit 20 is activated by the radio-frequency antenna control unit 29 and radiates radio-frequency magnetic resonance sequences into an examination space that is substantially formed by the patient-receiving region 14. The radio-frequency antenna unit 20 is also designed to receive magnetic resonance signals, in particular from the patient 15.

To control the basic field magnet 17, the gradient control unit 28 and the radio-frequency antenna control unit 29, the magnetic resonance apparatus 11 has a processor that forms an arithmetic unit 24. The arithmetic unit 24 centrally controls the magnetic resonance apparatus 11, such as for example, the execution of a predetermined imaging gradient echo sequence. Control information, such as imaging parameters, and reconstructed magnetic resonance images can be displayed for a user on a display unit 25, for example on at least one monitor, of the magnetic resonance apparatus 11. The magnetic resonance apparatus 11 also has an input unit (interface) 26, via which a user can enter information and/or parameters during a data acquisition procedure. The arithmetic unit 24 can include the gradient control unit 28 and/or radio-frequency antenna control unit 29 and/or the display unit 25 and/or the input unit 26.

The magnetic resonance apparatus 11 also has an image data acquisition unit 32. In the present case the image data acquisition unit 32 is formed by the scanner 13 together with the radio-frequency antenna control unit 29 and gradient control unit 28. The arithmetic unit 24 also has a determination unit 33. The magnetic resonance apparatus 11, together with the image data acquisition unit 32, input unit 26, display unit 25 and determination unit 33, is therefore configured to carry out an inventive method.

The illustrated magnetic resonance apparatus 11 can, of course, comprise further components that magnetic resonance apparatuses conventionally have. The general mode of operation of a magnetic resonance apparatus is known to those skilled in the art, so a detailed description of the further components is not necessary herein.

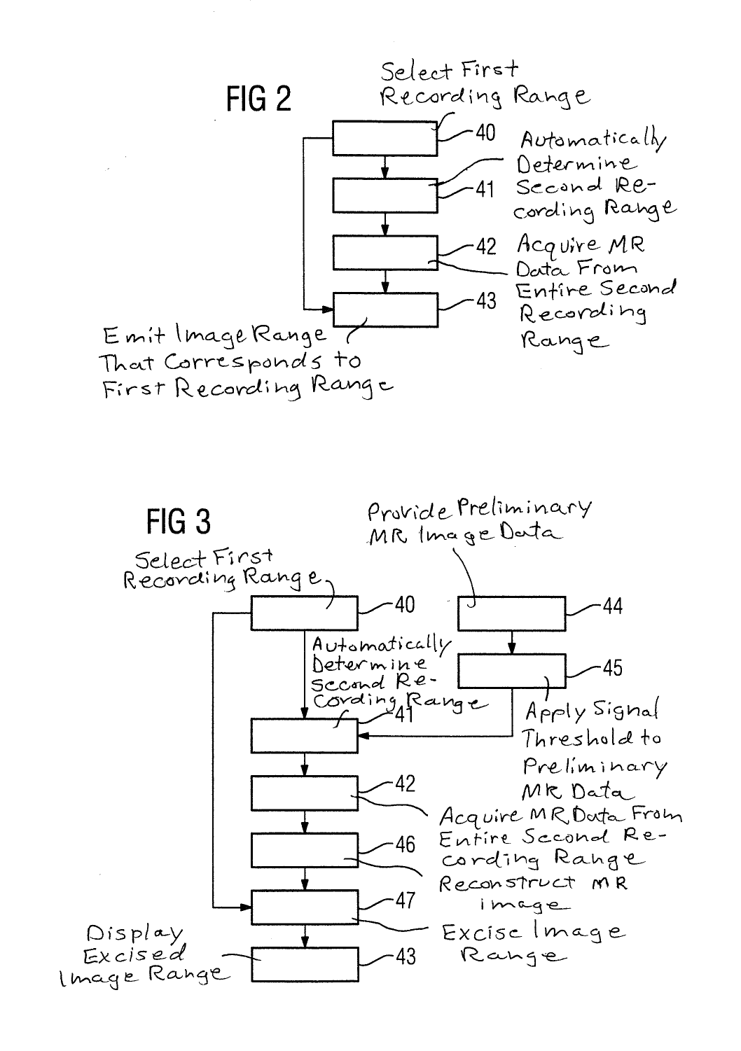

FIG. 2 is a flowchart of a first embodiment of an inventive method of magnetic resonance imaging by operation of the magnetic resonance apparatus 11.

In a first method step 40 a first recording range is selected via the input unit 26 of the magnetic resonance apparatus 11.

In a further method step 41, a second recording range is automatically determined by the determination unit 33 of the arithmetic unit 24 of the magnetic resonance apparatus 11. The second recording range is automatically determined in such a way that the second recording range includes the first recording range and a magnetic resonance signal-generating range.

In a further method step 42, magnetic resonance image data are acquired from the entire second recording range by the image data acquisition unit 32 of the magnetic resonance apparatus 11.

In a further method step 43, an image range of the magnetic resonance image data is emitted on the display unit 25 of the magnetic resonance apparatus 11, with the image range corresponding to the first recording range.

FIG. 3 is a flowchart of a second embodiment of an inventive method.

The following description is substantially limited to the differences from the exemplary embodiment in FIG. 2, with reference being made with respect to constant method steps to the description of the exemplary embodiment in FIG. 2. Substantially constant method steps are basically provided with the same reference characters.

The second embodiment of the inventive method shown in FIG. 3 substantially includes the method steps 40,41,42,43 of the first embodiment of the inventive method according to FIG. 2. In addition, the second embodiment of the inventive method shown in FIG. 3 includes additional method steps and sub-steps. A method sequence alternative to FIG. 3 is also conceivable which has only some of the additional method steps and/or sub-steps shown in FIG. 2. Of course a method sequence alternative to FIG. 3 can also have additional method steps and/or sub-steps.

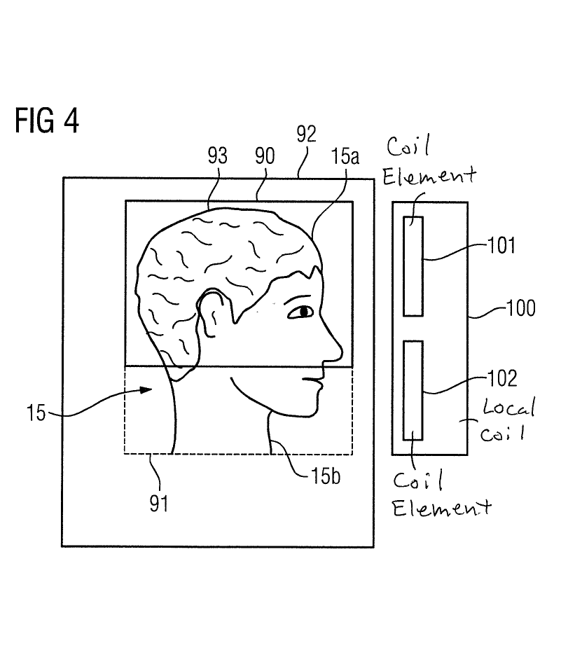

The selection of the first recording range 90 in the first method step 40 can be made, for example, on a previously recorded overview image. An overview image of this kind is shown as an example in FIG. 4. FIG. 4 shows an upper body region of a patient 15 that is formed by an upper head region 15a and a head and neck region 15b of the patient 15. In the case illustrated in FIG. 4, the first recording range 90 was chosen by a user via the input unit 26 such that the first recording range 90 includes only the upper head region 15a of the patient 15. The upper head region 15a is therefore of interest to the user while the head and neck region 15b is not of interest to the user.

The user would therefore like to have the first recording range 90 shown as the image range. To receive the magnetic resonance signals, two coil elements 101,102 of a local receiving coil 100 should be used. The two coil elements 101,102 are therefore activated to receive the magnetic resonance signals. A first coil element 101 of the two coil elements 101,102 is arranged on the upper head region 15a of the patient 15 while a second coil element 102 of the two coil elements 101 is arranged on the head and neck region 15b of the patient 15.

Before automatically determining the second recording range 91 in further method step 41, preliminary magnetic resonance image data are also acquired by the image data acquisition unit 32 in a further method step 44. The preliminary magnetic resonance image data are acquired using the same coil elements 101,102 as acquisition of the magnetic resonance image data. The preliminary recording range 92 of the preliminary magnetic resonance image data is selected to be as large as possible, as shown in FIG. 4. The preliminary magnetic resonance image data have a lower resolution than the diagnostic magnetic resonance image data recorded in further method step 42.

In a further method step 45, all signal ranges having a signal value that is greater than a signal threshold value are determined by the arithmetic unit 24 in the preliminary magnetic resonance image data. The signal threshold value is greater than a mean noise signal of the preliminary magnetic resonance image data, for example treble the mean noise signal. The signal ranges form a magnetic resonance signal-generating range 93. This is limited in FIG. 4 by the boundaries of the upper head region 15a together with the head and neck region 15b. The magnetic resonance signal-generating range 93 is dependent on the activated coil elements 101,102. In the present case the head and neck region 15b also forms part of the magnetic resonance signal-generating range 93 since the second coil element 102 is activated during acquisition of the preliminary magnetic resonance image data.

In a further method step 41 the second recording range 91 is then determined using the preliminary magnetic resonance image data by means of the determination unit 33. The second recording range 91 is determined such that it completely includes the magnetic resonance signal-generating range 93. The second recording range 91 also includes the first recording range 90. In the case shown in FIG. 4 the second recording range 91 therefore includes the upper head region 15a as well as the head and neck region 15b. The automatic determination of the second recording range 91 can also include an automatic determination by means of the determination unit 33 of at least one oversampling factor for the first recording range 90.

The magnetic resonance image data are then acquired in a further method step 42 from the entire second recording range 91. Therefore in the case shown in FIG. 4, magnetic resonance image data is acquired from the upper head region 15a and the head and neck region 15b, although the user has set only the upper head region 15a as the desired first recording range 90.

If, during acquisition of the magnetic resonance image data, a recording range is used which corresponds only to the first recording range 90, then magnetic resonance signals from the head and neck region 15b could fold in the first recording range 90. The second recording range 91 would be determined in such a way that signal folding is avoided in the image range, in the present case in the first recording range 90, during acquisition of the magnetic resonance image data. The magnetic resonance image data can also be non-selectively acquired from the entire second recording range 90 by means of the image data acquisition unit 33.

In a further method step 46 magnetic resonance images are reconstructed from the magnetic resonance image data by the arithmetic unit 24. The magnetic resonance images show the upper head region 15a and the head and neck region 15b. The magnetic resonance images can be stored. The magnetic resonance images are advantageously withheld from a user since they contain image information of no interest to the user, namely from the head and neck region 15b. The user therefore does not notice that magnetic resonance image data has been recorded from a larger, second recording range 91 and not from the selected first recording range 90.

In a further method step 47 an image range is excised from the magnetic resonance images by the arithmetic unit 24, with the image range corresponding to the first recording range 90. This image range is then also the image range of the magnetic resonance images of interest to the user.

In a further method step 43 the excised image range is then displayed for the user on the display unit 25.

The method steps of the inventive method shown in FIG. 2 and FIG. 3 are carried out by the magnetic resonance apparatus. For this purpose, the magnetic resonance apparatus 11 has the necessary software and/or computer programs which are stored in a memory unit of the magnetic resonance device. The software and/or computer programs include program code configured to carry out the inventive method when the computer program and/or software is run in the magnetic resonance apparatus 11 by means of an arithmetic unit of the magnetic resonance apparatus 11.

Although modifications and changes may be suggested by those skilled in the art, it is the intention of the inventor to embody within the patent warranted hereon all changes and modifications as reasonably and properly come within the scope of his contribution to the art.

I claim as my invention:

1. A method for magnetic resonance (MR) imaging, comprising:
via an input interface of a control computer for an MR data acquisition scanner, selecting a first 2D or 3D data acquisition range;
in said control computer, dependent on said first 2D or 3D data acquisition range, automatically determining a second 2D or 3D data acquisition range that comprises said first 2D or 3D data acquisition range and a 2D or 3D magnetic resonance signal-generating range;
from said control computer, operating said MR data acquisition scanner to acquire magnetic resonance image data from an entirety of said second 2D or 3D data acquisition range; and
in said control computer, reconstructing an MR image from the acquired MR image data, the reconstructed MR image corresponding to said first 2D or 3D data acquisition range.

2. A method as claimed in claim 1 comprising automatically determining said second 2D or 3D data acquisition range by automatic determination of at least one oversampling factor for said first 2D or 3D data acquisition range.

3. A method as claimed in claim 1 comprising providing said control computer with a previously-acquired preliminary MR image, and automatically determining said second 2D or 3D data acquisition range in said control computer using said preliminary MR image.

4. A method as claimed in claim 3 comprising determining said second 2D or 3D data acquisition range from said preliminary MR image so as to include all signal ranges of said preliminary MR image having a signal value that is larger than a predetermined threshold value.

5. A method as claimed in claim 4 comprising selecting said threshold value to be larger than an average noise signal of said preliminary magnetic resonance image.

6. A method as claimed in claim 3 wherein said preliminary MR image has a lower resolution than said reconstructed MR image.

7. A method as claimed in claim 1 comprising operating said MR data acquisition scanner from said control unit to acquire said MR data non-selectively from said entirety of said second 2D or 3D data acquisition range.

8. A method as claimed in claim 1 comprising automatically determining said second 2D or 3D data acquisition range to avoid signal folding in said MR signal-generating range during the acquisition of said MR image data.

9. A magnetic (MR) apparatus comprising:
a control computer having an input interface;
an MR data acquisition scanner operated by said control computer;
a display monitor in communication with said control computer;
said input interface of a control computer for an MR data acquisition scanner being configured to receive an input into said control computer that selects a first 2D or 3D data acquisition range;
said control computer being configured to automatically determine dependent on said first 2D or 3D data acquisition range, a second 2D or 3D data acquisition range that comprises said first 2D or 3D data acquisition range and a 2D or 3D magnetic resonance signal-generating range;
said control computer being configured to operate said MR data acquisition scanner to acquire magnetic resonance image data from an entirety of said second 2D or 3D data acquisition range; and
said control computer being configured to reconstruct an MR image from the acquired MR image data, the reconstructed MR image corresponding to said first 2D or 3D data acquisition range.
